(19) United States
(12) Patent Application Publication
(10) Pub. No.: US 2026/0021551 A1
(43) Pub. Date: Jan. 22, 2026

(54) CHEMICAL MECHANICAL POLISHING USING FLEXURE MOUNTED PAD

(71) Applicant: Applied Materials, Inc., Santa Clara, CA (US)

(72) Inventors: Steven M. Zuniga, Soquel, CA (US); Jay Gurusamy, Santa Clara, CA (US); Jeonghoon Oh, Saratoga, CA (US)

(21) Appl. No.: 18/778,609

(22) Filed: Jul. 19, 2024

(51) Int. Cl. B24B 37/10; B24B 37/04; B24B 37/30; B24B 53/017; H01L 21/306; H01L 21/3105; H01L 21/321

(52) U.S. Cl. CPC B24B 37/107; B24B 37/042; B24B 37/30; B24B 53/017; H01L 21/30625; H01L 21/31053; H01L 21/3212

(57) ABSTRACT

A chemical mechanical polishing method includes transferring a substrate onto a chuck supported by a drive shaft when the chuck is located at a first height, raising the chuck to a second height greater than the first height such that a top surface of the substrate is in contact with at least one polishing pad, polishing the substate by the at least one polishing pad, lowering, the chuck to a third height lower than the second height, and transferring the substrate off of the chuck.

### TECHNICAL FIELD

This disclosure relates to chemical mechanical polishing (CMP).

### BACKGROUND

An integrated circuit is typically formed on a substrate by the sequential deposition of conductive, semiconductive, or insulative layers on a silicon wafer. One fabrication step involves depositing a filler layer over a non-planar surface and planarizing the filler layer. For certain applications, the filler layer is planarized until the top surface of a patterned layer is exposed. A conductive filler layer, for example, can be deposited on a patterned insulative layer to fill the trenches or holes in the insulative layer. After planarization, the portions of the metallic layer remaining between the raised pattern of the insulative layer form vias, plugs, and lines that provide conductive paths between thin film circuits on the substrate. For other applications, such as oxide polishing, the filler layer is planarized until a predetermined thickness is left over the non-planar surface. In addition, planarization of the substrate surface is usually required for photolithography.

Chemical mechanical polishing (CMP) is one accepted method of planarization. This planarization method typically requires that the substrate be mounted on a carrier or polishing head. The exposed surface of the substrate is typically placed against a rotating polishing pad. The carrier head provides a controllable load on the substrate to push it against the polishing pad. An abrasive polishing slurry is typically supplied to the surface of the polishing pad.

### SUMMARY

The present disclosure provides an apparatus for “location specific polishing” of a substrate; the contact area of the polishing pad against the substrate is smaller than the surface area of the substrate so that polishing of the substrate is localized to a specific area.

In one aspect, a chemical mechanical polishing system includes: a chuck assembly including a chuck configured to hold a substrate during a polishing operation; a motor to rotate the chuck about a first axis; and a pad carrier assembly including a support that is movable along a radial direction relative to the first axis, a lateral actuator coupled the support to cause the support to move along the radial direction, a flexure having a first end secured to the support and a second end, a pad carrier/attachment secured to a bottom side of the second end of the flexure and configured to receive and hold a polishing pad, a support arm extending from the support over the flexure such that the support arm and the flexure move together along the radial direction with the second end of the flexure vertically movable relative to the support arm, and a pad carrier actuator secured to the arm to apply a downward pressure to a top of the flexure.

In another aspect, a chemical mechanical polishing system includes: a chuck assembly including a chuck configured to hold a substrate during a polishing operation; a motor to rotate the chuck about a first axis; and multiple a pad carrier assemblies arranged around the first axis. Each pad carrier assembly of the plurality pad carrier assemblies can include a support that is movably along a radial direction relative to the first axis, a lateral actuator coupled the support to cause the support to move along the radial direction, a pad carrier/attachment supported from the support and configured to receive and hold a polishing pad, and a pad carrier actuator to apply a downward pressure to the pad carrier.

In another aspect, a chemical mechanical polishing system includes: a chuck assembly including a chuck configured to hold a substrate during a polishing operation; a motor to rotate the chuck about a first axis; a pad carrier assembly that includes a support that is movably along a radial direction relative to the first axis, a lateral actuator coupled the support to cause the support to move along the radial direction, a pad carrier supported from the support and configured to receive and hold a polishing pad, and a pad carrier actuator to apply a downward pressure to the pad carrier; and a conditioner ring positioned concentrically with the chuck. The support can have a sweep range along the radial direction from a first position in which the polishing pad attached to the pad carrier is positioned over the chuck for polishing of the substrate and a second position in which the polishing pad is positioned over the conditioner ring for conditioning of the polishing pad.

In another aspect, a chemical mechanical polishing system includes: a chuck assembly including a chuck configured to hold a substrate during a polishing operation; a motor to rotate the chuck about a first axis; a pad carrier assembly that includes a support that is movably along a radial direction relative to the first axis, a lateral actuator coupled the support to cause the support to move along the radial direction, a pad carrier supported from the support and configured to receive and hold a polishing pad, and a pad carrier actuator to apply a downward pressure to the pad carrier; a substrate transfer robot to load and/or unload the substrate from the chuck; and a vertical actuator to move the chuck vertically between a raised position in which the substrate is positioned to contact the polishing pad and a lowered position in which the substrate on the chuck is accessible to the substrate transfer robot.

In another aspect, a method includes: transferring a substrate onto a chuck supported by a drive shaft when the chuck is located at a first height; raising, by a vertical actuator coupled to the drive shaft, the chuck to a second height greater than the first height, such that a top surface of the substrate is in contact with at least one polishing pad; polishing, by the at least one polishing pad, the substrate; lowering, by the vertical actuator, the chuck to a third height lower than the second height; and transferring the substrate off of the chuck.

Implementations may include one or more of the following features. The pad carrier actuator may include a membrane secured to a bottom of the arm to form a pressurizable chamber. The pad carrier actuator may include a membrane secured to a bottom of the arm to form a pressurizable chamber. The system may include a controller configured to cause the lateral actuator to radially oscillate the pad carrier and polishing pad during polishing of the substrate by the polishing pad.

The system may include a conditioner ring positioned concentrically with the chuck. The support may have a sweep range along the radial direction from a first position in which the polishing pad attached to the pad carrier is positioned over the chuck for polishing of the substrate and a second position in which the polishing pad is positioned over the conditioner ring for conditioning of the polishing pad. The conditioner ring may be rotatable about the first axis. A vertical actuator may move the chuck vertically through an aperture in the conditioner ring.

A vertical actuator may move the chuck vertically between a raised position in which the substrate is positioned to contact the polishing pad and a lowered position in which the substrate is below the conditioner ring. A controller may be configured to cause the lateral actuator to move the pad carrier and polishing pad from the first position to the second position after completion of polishing of the substrate. The controller may be configured to cause the lateral actuator to radially oscillate the pad carrier and polishing pad during polishing of the substrate by the polishing pad.

A substrate robot transfer robot may be configured to transfer the substrate into or out of the system. A vertical actuator may move the chuck vertically between a raised position in which the substrate is positioned to contact the polishing pad and a lowered position in which the substrate is accessible to the substrate transfer robot. The chuck may include lift pins configured to rise out of and recede back into the chuck to transfer substrate to the substrate transfer robot.

The plurality of pad carrier assemblies may be arranged at equal angular intervals around the first axis. The plurality of pad carrier assemblies may be exactly four pad carrier assemblies. A controller may be configured to cause the lateral actuators of the plurality of pad carrier assemblies at the same radial distance from the first axis during polishing of the substrate. A controller may be configured to cause the lateral actuators of the plurality of pad carrier assemblies to radially oscillate the pad carriers and polishing pads in synchronization during polishing of the substrate.

Each pad carrier assembly may include a flexure having a first end secured to the support and a second end, and a support arm extending from the support over the flexure such that the support arm and the flexure move together along the radial direction with the second end of the flexure vertically movable relative to the support arm. The pad carrier/attachment may be secured to a bottom side of the second end of the flexure. The pad carrier actuator can be secured to the arm to apply a downward pressure to a top of the flexure.

A controller may be configured to cause the lateral actuator to move the pad carrier and polishing pad from the first position to the second position after completion of polishing of the substrate. A vertical actuator may move the chuck vertically through an aperture in the conditioner ring between a raised position in which the substrate is positioned to contact the polishing pad and a lowered position in which the substrate is below the conditioner ring. A substrate robot transfer robot may be configured to load or unload the substrate from the chuck at the lower position. A horizontally extending support plate may support the support of the pad carrier assembly. The lowered position can be below the horizontally extending support plate.

The substrate transfer robot may have an end effector to hold the substrate, the end effector movable along a horizontal axis. The end effector may be constrained to move along the horizontal axis. The end effector may be constrained to move along the horizontal axis. The support may have a sweep range along the radial direction from a first position in which the polishing pad attached to the pad carrier is positioned over the chuck for polishing of the substrate and a second position in which the polishing pad is positioned over the conditioner ring for conditioning of the polishing pad. The vertical actuator may move the chuck vertically through an aperture in the conditioner ring.

Polishing the substrate may include rotating, by a rotational motor coupled to the drive shaft, the chuck, such that the substrate rotates relative to the at least one polishing pad. Polishing the substrate may include oscillating, by a sweep arm, the at least one polishing pad along a radial direction. Polishing the substrate may include, while oscillating the at least one polishing pad along the radial direction, rotating, by a rotational motor coupled to the drive shaft, the chuck. Oscillating the at least one polishing pad along the radial direction includes operating a horizontal actuator engaged with a rail, the horizontal actuator coupled to and supporting the sweep arm. The at least one polishing pad may includes a first polishing pad and a second polishing pad, and oscillating the at least one polishing pad along a radial direction may include oscillating the first polishing pad a first rate and oscillating the second polishing pad a second rate.

A sweep arm may move an assembly coupled to the at least one polishing pad along a radial direction such that the at least one polishing pad overlies a conditioning ring, and the at least one polishing pad may be conditioned with the conditioning ring.

Transferring the substrate off of the chuck may be simultaneous to at least one of moving the at least one polishing pad along the radial direction and conditioning the at least one polishing pad with the conditioning ring. Conditioning the at least one polishing pad may include rotating a rotational motor coupled to a belt surrounding and in contact with the conditioner ring and rotational motor, such that rotation of the rotational motor causes rotation of the conditioner ring. Polishing the substrate may include controlling a pressure of the at least one polishing pad on the substrate by changing a pressure in a pressurizable membrane coupled to the at least one polishing pad and separated from the at least one polishing pad by a flexure. The polishing pad may be replaced without removing the pressurizable membrane.

Transferring the substrate onto and off the chuck may include raising and lowering lift pins embedded in the chuck to contact the substrate while a robotic arm moves along a horizontal direction above the chuck.

Advantages of the invention optionally includes, but are not limited to, one or more of the following. The flexure support enables nearly 360° coverage of a set of arcuate pads on the substrate for polishing of an annular zone on the substrate, which can increase polishing rate, and thus throughput. Non-uniform polishing of the substrate can be reduced, especially at the edges of the substrate, and the resulting flatness and finish of the substrate are improved. Additionally, the described apparatus and system allows for substrate transfer that occurs below the polishing level, which can increase throughput.

Other aspects, features, and advantages of the invention will be apparent from the description and drawings, and from the claims.

### DESCRIPTION OF DRAWINGS

FIG. 1 is side view of a polishing system in a first configuration.

FIG. 2 is side view of the polishing system of FIG. 1 in a second configuration.

FIG. 3 is side view of the polishing system of FIG. 1 in a third configuration.

FIG. 4 is a plan view of a wafer and polishing pads from the polishing system of FIG. 1.

FIG. 5 is a plan view of the wafer, the polishing pads, and a lateral actuator with a flexure from the polishing system of FIG. 1.

FIG. 6 is a side view of a single lateral actuator and the flexure.

FIG. 7 is a plan view of polishing pad supports from the polishing system of FIG. 1.

FIG. 8 is a side view of the polishing system of FIG. 1 in a fourth position.

FIG. 9 is a plan view of a conditioning assembly from the polishing system of FIG. 1.

Like reference symbols in the various drawings indicate like elements.

### DETAILED DESCRIPTION

Some chemical mechanical polishing processes result in thickness non-uniformity across the surface of the substrate. For example, a bulk polishing process can result in under-polished regions on the substrate. To address this problem, after the bulk polishing it is possible to perform a “touch-up” polishing process that focuses on portions of the substrate that were underpolished, e.g., “location specific polishing” (LSP).

Some bulk polishing processes result in radially non-uniform polishing. A polishing pad that rotates about a center of the substrate may be able to compensate for concentric rings of non-uniformity, but may have a relatively low polishing rate. However, a set of small arcuate pads that undergo an orbiting motion about the center of the substrate can be used to compensate for radially non-uniform polishing while maintaining a relatively high throughput. Each arcuate pad can be mounted on a flexure that is attached to a sweep mechanism, permitting the system to be adaptable to under-polishing at a variety of different radial positions. The pad and a pressure control module can sweep outward to engage a pad conditioner that can rotate about a central axis. A chuck can secure the wafer as well as rotate about a central axis and move up and down in a vertical direction to enable wafer transfer below the pad conditioner. As a result, simultaneous pad conditioning and wafer transfer is possible.

This architecture also allows for separating the polishing pad from a pressurizable chamber used to apply a downward force onto the polishing pad. The ability to separately remove the polishing pad from the actuating chamber can reduce operating costs, since polishing pads tend to require replacement more frequently than the pressurizable chamber.

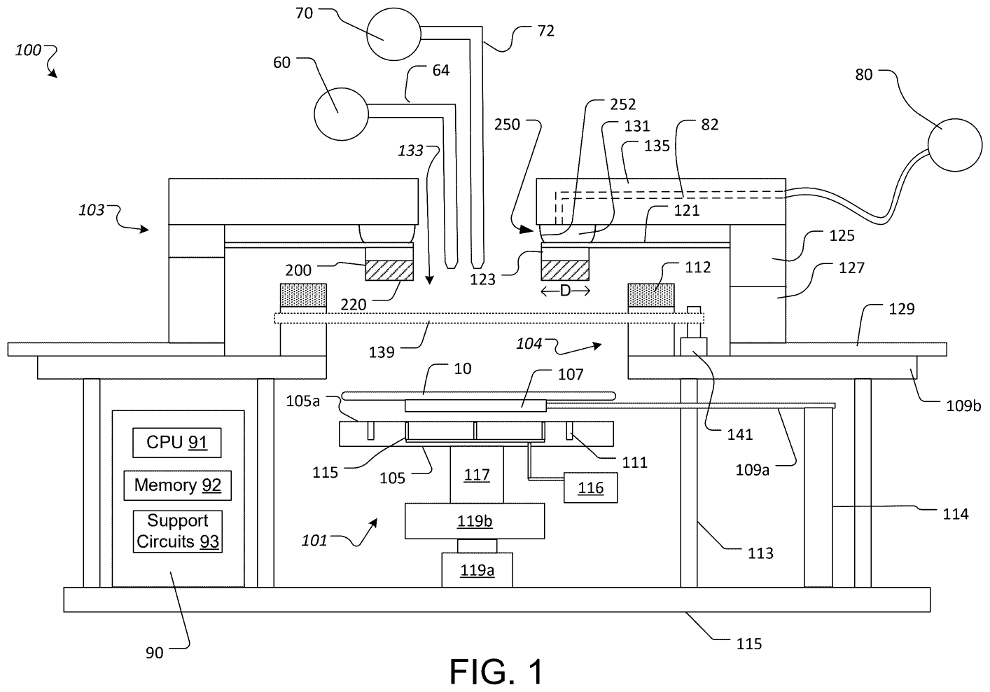

With reference to FIG. 1, a polishing system 100 can be configured for polishing localized regions of a substrate 10. The polishing system 100 can include a chuck assembly 101 for loading the substrate 10, a polishing assembly 103 for polishing the substrate 10, a conditioning assembly 104 for conditioning a polishing pad of the polishing assembly 103, and a controller 90, e.g., a programmable computer, for controlling the various assemblies in the polishing system 100. The controller 90 can include a central processing unit 91, memory 92, and support circuits 93. The controller's 90 central processing unit 91 executes instructions loaded from memory 92 via the support circuits 93 to allow the controller to receive input based on the environment and desired polishing parameters and to control the various actuators and drive systems.

Hereinafter, a process of loading a wafer, polishing the wafer, unloading the wafer, and conditioning the polishing pads will be described. Although some reference numerals introduced in FIG. 1 will not be discussed until later figures are introduced for the sake of clarity, those reference numerals are provided to show how the various components interrelate.

### Loading

The system 100 includes a substrate transfer robot 114 that has an end effector 107 at the end of a robot arm 109a to move a substrate 10 horizontally to load or unload the substrate from the chuck assembly 101.

The chuck assembly 101 includes a chuck 105, a drive shaft 117, and motors 119a and 119b. The chuck assembly 101 includes a chuck 105 is supported by a drive shaft 117 that is connected to a motor 119a and a vertical actuator 119b. The motor 119a can rotate the drive shaft 117 about a central axis 118a of the drive shaft 117, and the vertical actuator 119b can raise or lower the chuck 105 to control the vertical position of the chuck 105, e.g., through an aperture 133 of a conditioner ring 112. The actuator 119b can raise the chuck 105 so that the upper surface of the substrate 10 is at a same vertical height as a surface of the polishing pad. Although FIG. 1 illustrates the motor 119b as above the vertical actuator 119b, the positions could be reversed.

The top surface 105a of the chuck 105 provides a loading area large enough to accommodate the substrate 10 to be processed. For example, the substrate 10 can be a 200 to 450 mm diameter substrate. The top surface of the chuck 105 contacts the back surface of the substrate 10 (i.e., the surface that is not being polished) and maintains its position.

In some implementations, the chuck 105 is about the same radius as the substrate 10, or larger. In some implementations, the chuck 105 is slightly narrower than the substrate, e.g., by 1-2% of the substrate diameter. In this case, when placed on the chuck 105, the edge of the substrate 10 slightly overhangs the edge of the chuck 105. This can provide clearance for an edge grip robot to place the substrate on the support. In some implementations, the chuck 105 is wider than the substrate, e.g., by 1-10% of the substrate diameter. In either case, the chuck 105 can make contact with a majority of the surface the backside of the substrate.

In some implementations, passages 115 through the chuck 105 extend from holes in the surface 105a of the chuck 105 to a vacuum source 116. The vacuum source 116 can create a pressure differential between the top surface and bottom surfaces of the substrate 10, thus chucking the substrate to the chuck 115.

FIG. 1 is side view of the polishing system 100 in a first configuration where the substrate 10 is being loaded onto the chuck 105. In particular, the chuck 105 is in a lowered first configuration below the polishing assembly 103, and the substrate 10 is initially supported by the end effector 107 of the robot 114. The end effector 107 is attached to a robot arm 109a that can move at least in a horizontal direction to move the substrate, e.g., from a transfer station, to position the substrate 10 over the chuck 105.

In some implementations, lift pins 111 embedded within the chuck 105 can rise up from the chuck 105 to temporarily support the substrate 10 when the end effector 107 is positioned above the chuck 105 and close enough for the lift pins 111 to contact the substrate 10. When the lift pins 111 are supporting the substrate 10, the robot arm 109a can withdraw, e.g., move in a horizontal direction away from the chuck 105. Then the lift pins 111 can retract back into the chuck 105 until the substrate 10 is in contact with the top surface 105a of the chuck 105.

Alternatively, if the chuck 105 is narrower than the substrate and the end effector is an edge grip or edge support ring, then transfer of the substrate 10 onto the top surface 105a of the chuck 105 can be accomplished simply by raising the chuck 105 with the vertical actuator 109a.

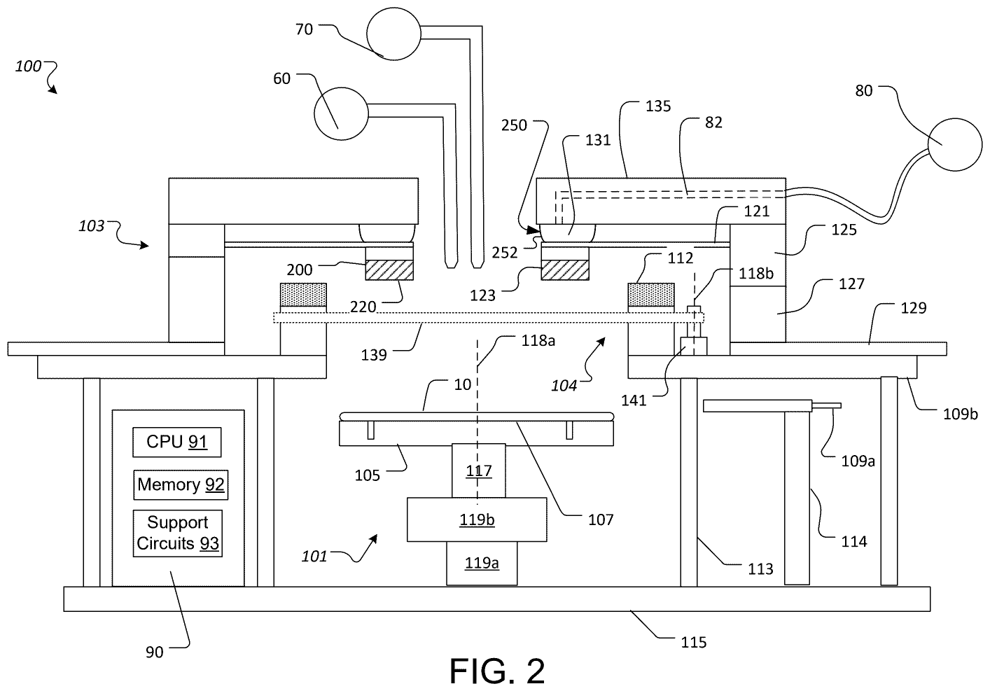

FIG. 2 is side view of the polishing system 100 in a second configuration. In this second configuration, the substrate 10 is in contact with the chuck 105, with the lift pins 111 in a withdrawn position, e.g., embedded within the chuck 105.

### Polishing

The polishing assembly 103 includes polishings pads 200 positioned to be driven downwardly by actuator 250. The actuator 250 is supported at the end of a horizontally movable support arm 135. The actuator 250 can be a pressurizable chamber 131, e.g., a chamber formed by a bladder or by attachment of a membrane 252 to the underside of the support arm 135. The polishing pads 200 are supported with polishing surfaces 220 in a facedown orientation to contact an exposed surface of the substrate 10. In particular, each polishing pad 200 is supported by a flexure 121 that extends from the support arm 135.

The end of the flexure 121 is positioned below the actuator 250 such that downward pressure of the actuator 250 on the flexure 121 causes the polishing pad 200 to apply a downward force to the substrate 10. For example, when pressure is applied from pressure source 80, the pressurizable chamber 131 inflates, which causes the membrane 252 to expand outwardly to contact the flexure 121.

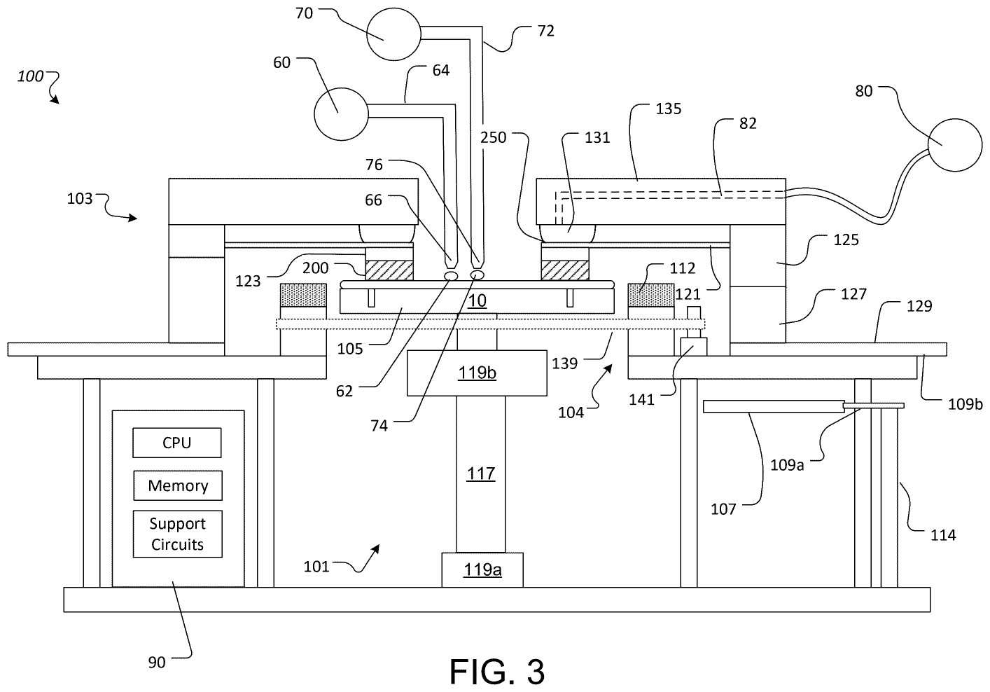

FIG. 3 is a side view of the polishing system 100 in a third configuration in which the vertical actuator 119b has raised the chuck 105 relative to FIG. 2. In the raised position, the substrate 10 contacts the polishing surfaces 220 of polishings pads 200.

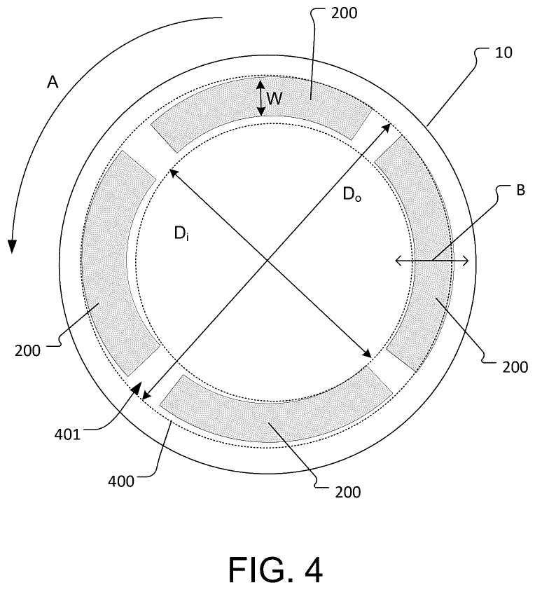

The polishing pads 200 can have a lateral width W (see FIG. 4) along the radius of the substrate 10 that is smaller than the radius of the substrate 10. For example, for the width W of the polishing pad 200 can be about can be about 1-10% of the diameter of the substrate 10. For example, for a substrate 10 that ranges from 200 mm to 300 mm in diameter, the polishing pad surface 220 can have a width of 2-30 mm, e.g., 3-10 mm, e.g., 3-5 mm. Narrower polishing pads 200 provide more precision, but can be slower to use if the under-polished area is relatively wider.

The polishing pad 200 can be a material suitable for contacting the substrate 10 during chemical mechanical polishing. For example, the polishing pad material can include polyurethane, e.g., a microporous polyurethane, for example, an IC-1000 material. The polishing pad 200 can have a thickness of about 0.5 to 7 mm, e.g., about 2 mm.

Each polishing pad 200 is secured to the bottom of a corresponding flexure 121 by an attachment 123, e.g., a pad holder such as an adhesive, or one or more mechanical fasteners such as clamps. Due to being attached to the flexure 121, each polishing pad 200 has a range of vertical motion. The range of vertical motion can depend on the pad lifetime, e.g., the range compensates for the gap due to pad wear, e.g., 10 to 100 milli-inches. However, the flexure 121 prevents the polishing pad 200 from simply descending with the substrate 10 when the chuck 105 is lowered to the loading position.

The flexure 121 is attached to a sweep arm 125 that allows the flexure 121 to sweep laterally. The sweep arm 125 is supported by a drive motor 127 engaged to a rail 129, e.g., by a geared wheel. The drive motor 127 can cause the polishing assembly and thus flexure 121 to move along the horizontal direction aligned with the rail 129.

Where the actuator is provided by a pressurizable chamber 250, the polishing system 100 includes a controllable pressure source 80, e.g., a pump, to apply a controllable pressure to the interior of the pressurizable chamber 250. The pressure source 80 can be connected to the pressurizable chamber 250 by a conduit 82, such as flexible tubing, that passes through the support arm 135. Where the actuator is provided by a motor, e.g., a linear screw actuator or a linear motor, a current source is connected to the actuator.

During polishing, the motor 119b can rotate the drive shaft 117 such that the chuck 105 and substrate 10 rotate about the central axis 118a of the drive shaft 117. The polishing system 100 includes a port 66 to dispense a polishing liquid 62, such as an abrasive slurry onto the substrate 10. Optionally the polishing system includes a reservoir 60 to hold the polishing liquid 62. A conduit 64, e.g., flexible tubing, can transport the polishing liquid 62 from the reservoir 60 to the port 66, where it flows onto the surface of the substrate 10. The reservoir 60 can include a pump to supply the polishing liquid at a controllable rate through the conduit 64. Assuming the polishing pads 200 have an arcuate shape, by dispending the polishing liquid 62 near the center of the substrate, the polishing pad impedes the slurry from sliding off of the substrate 10 due to the centripetal force while polishing.

After polishing, cleaning fluid 74 from a cleaning fluid source 70 can flow from a port 76 onto the substrate 10 to remove debris built up during polishing. The cleaning fluid 74 can be, for example, deionized water. A conduit 72, e.g., flexible tubing, can be used to transport the cleaning fluid 74 from the reservoir 70 to the port 76, where it flows onto surface of the substrate 10.

Each of the reservoir 60, reservoir 70, and controllable pressure source 80 can be mounted on a support structure or on a separate frame holding the various components of the polishing system 100.

FIG. 4 is a plan view of the substrate 10 and polishing pads 200 from the polishing system 100. Each polishing pad 200 can have an arcuate shape, e.g., an arc of an annulus. Although four polishing pads 200 are depicted in this example, a smaller number, e.g., 2 or 3, or a larger number, e.g., up to 10, is possible. In some implementations, the polishing pads 200 are equally angularly spaced. In this example, there are four polishing pads, so the center of each polishing pad 200 is spaced by 90° (360/4=90). Each pad can subtend an angle of 20-90° about the center of the substrate. Depending on the radial position of the pads 220, all of the pads together can subtend a total angle of about 270-350° degrees about the center of the substrate.

The polishing pads 200 can together form an annulus with gaps 401 in an annular zone 400. The gaps 401 permit the polishing pads 200 to sweep along a radial direction B without touching one another. The wafer rotates in the direction indicated by arrow A due to the rotation of motor 119a. In the configuration depicted in FIG. 4, polishing occurs in the annular zone 400 having inner and outer diameters Dᵢ and Dₒ.

In some implementations, as illustrated in FIG. 4, the polishing pads 200 are positioned by the actuator such that the outer and inner diameters Dₒ and Dᵢ of the annular zone 400 are both smaller than the diameter of the substrate 10. In some implementations, the polishing pads 200 are positioned such that the outer diameter Do is aligned with the outer edge of the substrate 10. For example, the polishing pads 200 can be sized to perform localized polishing of the outer 15 mm of the substrate 10. In some implementations, the polishing pads 200 are positioned such that the outer diameter Do is beyond the outer edge of the substrate 10; only part of each polishing pad 200 will contact the substrate 10.

The radial position of the annular zone 400 can change when the polishing pads 200 sweep along the radial direction B, either increasing or decreasing the inner and outer diameters Dₒ and Dᵢ of the annular zone 400.

Although there are gaps 401 between the polishing pads 200, the substrate 10 should be evenly polished within the annular zone 400 due to rotation of the substrate (shown by arrow A). The size 401 of the gaps depends on the radial positioning of the polishing pads 200; as the polishing pads 200 are moved toward the center of the substate the gaps 401 will get smaller. The controller can keep the polishing pads 200 at a minimum distance from the center of the substrate 10 avoid having the pads collide.

Because the gaps can be relatively small, e.g., less than 90° total of substrate circumference, e.g., less than 45°, e.g., less than 25°, e.g., less than 10°, a relatively high polishing rate can be achieved in the annular zone 400.

In some implementations, one or more polishing pads 200 move laterally, e.g., oscillate along a radial direction, during polishing. For example, the support 125 and flexure 121 can sweep one or more of the polishing pads 200 slowly (compared to the rotational motion of the substrate 10) across a region to be polished. For example, the relative horizontal velocity between the substrate 10 and the polishing pad 200 can be less than 5%, e.g., less than 2%, of the instantaneous rotational velocity provided of substrate 10. On the other hand, in some implementations, the polishing pads 200 can be held in a fixed lateral position during the polishing operation.

In some implementations, one or more polishing pads 200 move independently during polishing. For example, each of the four polishing pads 200 can move at a different rate while oscillating along the radial direction. As another example, although the polishing pads 200 are depicted located the same distance from the center of the substrate 10, each of polishing pads 200 can be located at a different radial position relative to the center of the substrate 10.

In some implementations, the lateral cross-sectional shape, i.e., a cross-section parallel to the polishing pad surface 220, of the polishing pad 200 (and the polishing pad surface 220) can be nearly any shape, e.g., circular, square, elliptical, or a circular arc.

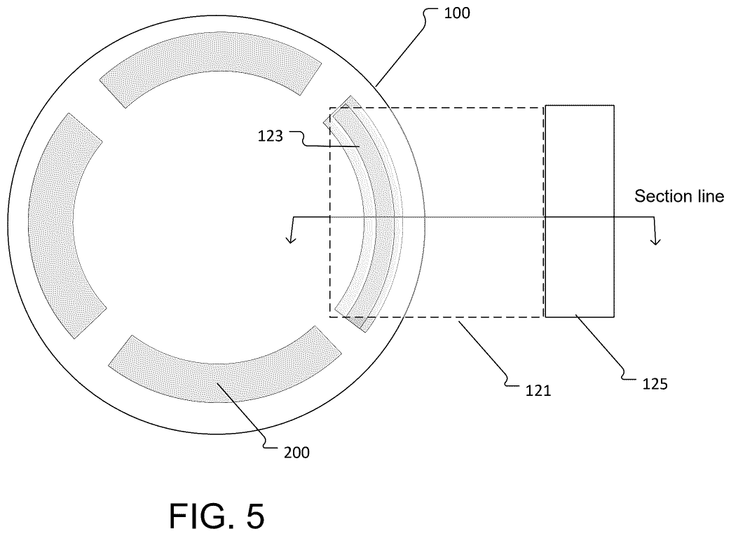

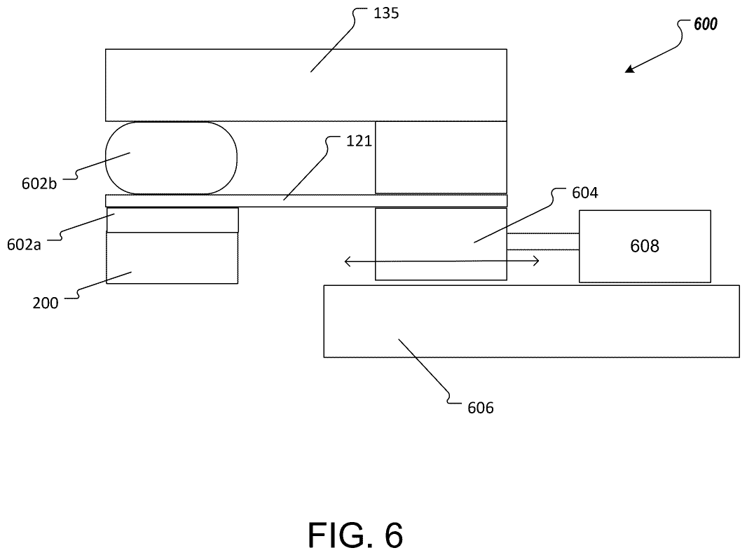

FIG. 5 is a plan view of the substrate 10, the attachment 123, the flexure 121 (in phantom), the support arm 135, and the polishing pads 200. The section line indicates how FIG. 5 relates to the cross-sectional view of FIG. 6. The attachment 123 attaches the polishing pad 200 to the flexure 121 which can move in a horizontal direction, e.g., the radial direction relative to the substrate 10. Although only one of the polishing pads 200 is depicted as being attached to an attachment 123, flexure 121, and sweep arm 125, and thus capable of lateral movement, all of the polishing pads 200 can be configured this way, each having its own respective attachment 123, flexure 121, and sweep arm 125.

FIG. 6 is a side view of a single lateral actuator 600 and the flexure 121. The lateral actuator 600 is a variation on the mechanism that provides the polishing pads 200 with the ability to sweep along the horizontal direction. In some implementations, the polishing pad 200 is suspended by the flexure 121 below a bladder 602a. The flexure 121 is attached to a movable support 604 engaged to a stationary frame 606. An actuator 608 can push or drag the movable support along the horizontal direction indicated by the arrows along the stationary frame, thus enabling lateral motion of the polishing pad 200. For example, the actuator 608 can include a linear screw that extends to the movable support 604. Another bladder 602b is coupled to a pressure control system through a support 610.

Due to the architecture of the polishing system 100, the pressurizable chamber 131 (formed by bladder 602b or membrane 252) within the polishing assembly 103 is decoupled from the polishing pad 200, which allows for replacing the polishing pad 200 without disturbing the pressurizable chamber 131, which tends to have a longer lifespan than the polishing pad 200. Additionally, due to the decoupling of the pressurizable chamber 250 and polishing pad 200, the rigidity of the bladder 602b or membrane 252 can be independent of the location of the polishing pad 200. For example, when the desired polishing profile demands shear force being transferred from the polishing pad 200, the pressurizable chamber 250 can have certain requirements, e.g., being rigid. With the decoupling, however, the membrane can be soft.

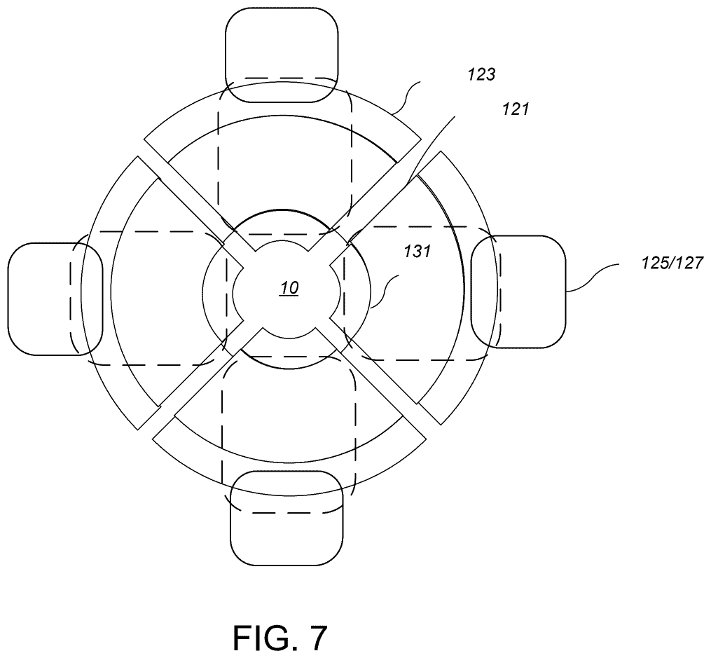

FIG. 7 is a plan view of an example of the polishing assembly 103 from the polishing system 100. In this example, there are four arcuate polishing pads 200, and the flexure 121, attachment 123, sweep arm 125, drive motor 127, and pressurizable chamber 131 for each polishing pad 200 is illustrated. Each polishing pad 200 is connected to a pressurizable membrane 131 to control pressure on the substrate 10 while polishing. Each polishing pad 200 is connected to the sweep arm 125 (supported by drive motor 127) through the flexure 121, which is coupled to the polishing pad 200 through attachment 123. As depicted in FIG. 7, each flexure can have an arcuate, annular shape, e.g., an arc segment of an annulus.

Working in concert, the four polishing pads 200 can polish with precision and accuracy. In some implementations, a subset of the polishing pads 200 can be positioned over the substrate 10 during polishing to allow polishing the center of the substrate 10, e.g., regions of the substrate 10 within a radius less than the smallest possible inner diameter when all of the polishing pads are brought into contact.

### Conditioning and Wafer Transfer

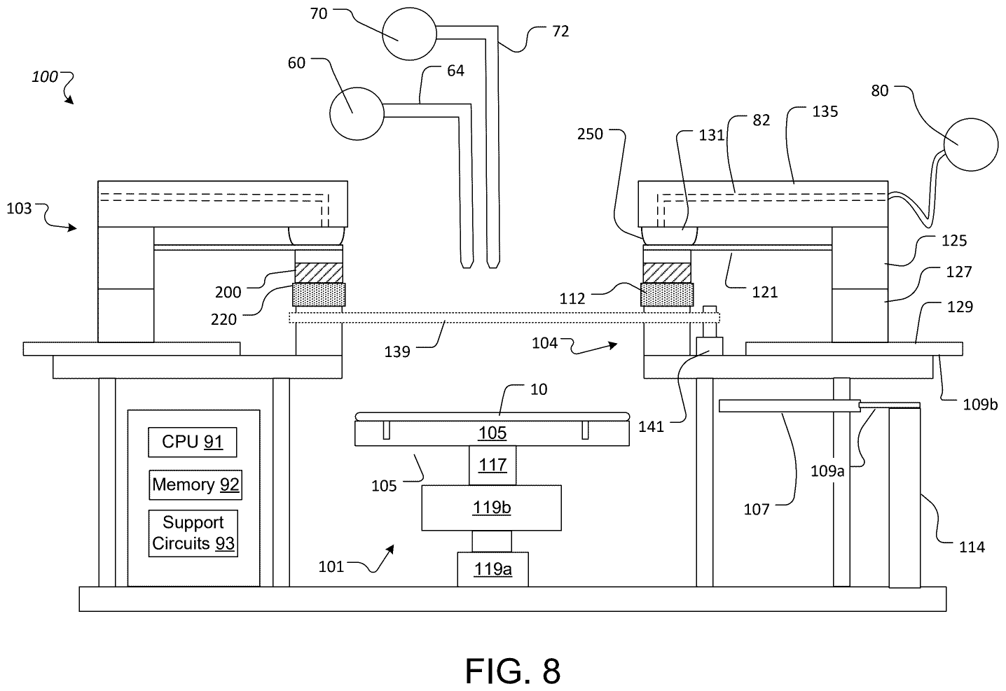

FIG. 8 depicts the polishing system 100 in a fourth configuration. After polishing is complete, the substrate 10 can be lowered to a position beneath the polishing assembly 103 by the actuator 119b lowering the chuck 105. The robot arm 109a can pick up the substrate 10 from the chuck 105 and transfer the polished substrate out of the polishing system 100. In general, the steps of loading can be performed in reverse. For example, the lift pins can lift the substate 10, the end effector 107 can be inserted by the robot arm 109a below the substrate 10, and the lift pins can retract to leave the substrate held by the end effector.

Before, after, or simultaneous with the transfer the substrate 10, the polishing pads 200 can be conditioned by the conditioner assembly 104. The conditioner assembly 104 includes a conditioner ring 112, and a mechanism for rotating the conditioner ring 112 relative to the polishing pads 200.

In the configuration in FIG. 8, the drive motors 127 have moved the supports 125 and polishing pads 200 radially outward relative to the polishing position, such that the polishing pads 200 are aligned with and positioned over the conditioner ring 112. The conditioner ring 112 can abrade the polishing pad 200 to maintain the polishing pad 200 in a consistent abrasive state. The polishing pads 200 and conditioner ring 112 can be brought into contact by the actuator 250 pressing the substrate moving along the rail 129.

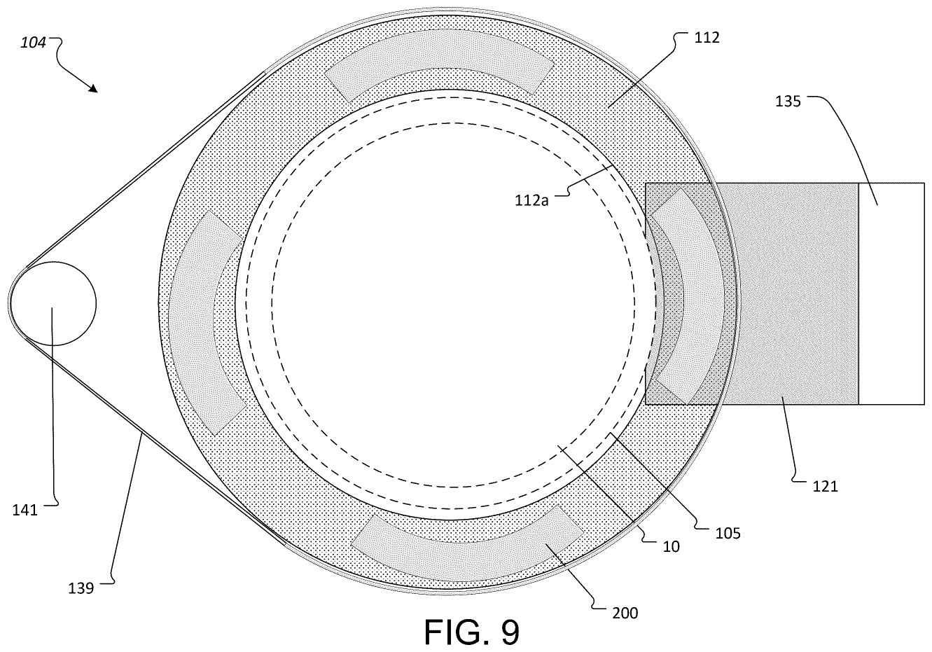

The conditioner ring 112 has an inner diameter 112a (see FIG. 9) that is larger than the largest outer diameter of the chuck 105 and larger than the diameter of the substrate 10. This permits the chuck 105 and substrate 10 to fit through or sit within the conditioner ring 112 when the chuck 105 is in the raised position for the polishing operation (see FIG. 3). The conditioner ring 112 and the chuck 105 can have a common center axis.

FIG. 9 is a plan view of a conditioning assembly 104 from the polishing system 100. As depicted in the plan view, during conditioning, the polishing pads 200 are above the conditioner ring 112. The polishing pads 200 are attached to the flexure 121 supported by the support. During conditioning, the conditioner ring 112 rotates about a central axis (118b in FIG. 2) to condition the polishing pads 200.

In some implementations, the rotation mechanism for the conditioner ring is a belt 139 engaged with a motor 141. As the motor 141 rotates about the central axis 118b, it pulls a portion of the belt 139 in contact with the motor 141 in the direction of rotation, causing the entire belt 139 to rotate. As the belt 139 rotates, it pulls the conditioner ring 112 along the direction of rotation. As a result, the polishing pads 200 are conditioned by the rotating conditioner ring 112. Other mechanisms of driving the rotation of the conditioning ring 112 are possible.

In some implementations, while the conditioner ring 112 rotates, the polishing pads 200 oscillate along the radial direction to achieve additional control while conditioning. In some implementations, conditioning is performed by just the polishing pads 200 rapidly oscillating against the conditioner ring 112 while the conditioner ring 112 remain stationary. Since the polishing pads 200 do not form concentric arcs in any lateral position, the conditioner ring 112 is wider than the polishing pads 200 when they are in a concentric position.

Accordingly, other embodiments are within the scope of the following claims.

What is claimed is:

1. A method comprising:
transferring a substrate onto a chuck supported by a drive shaft when the chuck is located at a first height;
raising, by a vertical actuator coupled to the drive shaft, the chuck to a second height greater than the first height, such that a top surface of the substrate is in contact with at least one polishing pad;
polishing, by the at least one polishing pad, the substrate;
lowering, by the vertical actuator, the chuck to a third height lower than the second height; and
transferring the substrate off of the chuck.

2. The method of claim 1, wherein polishing the substrate comprises rotating, by a rotational motor coupled to the drive shaft, the chuck, such that the substrate rotates relative to the at least one polishing pad.

3. The method of claim 2, wherein polishing the substrate comprises oscillating, by a sweep arm, the at least one polishing pad along a radial direction.

4. The method of claim 3, wherein polishing the substrate comprises, while oscillating the at least one polishing pad along the radial direction, rotating, by a rotational motor coupled to the drive shaft, the chuck.

5. The method of claim 4, wherein oscillating the at least one polishing pad along the radial direction comprises operating a horizontal actuator engaged with a rail, the horizontal actuator coupled to and supporting the sweep arm.

6. The method of claim 1, wherein the at least one polishing pad comprises a first polishing pad and a second polishing pad, and oscillating the at least one polishing pad along a radial direction comprises oscillating the first polishing pad a first rate and oscillating the second polishing pad a second rate.

7. The method of claim 1, wherein the at least one polishing pad comprises a first polishing pad and a second polishing pad, and the first and second polishing pads are located at different radial distances relative to a center of the substrate.

8. The method of claim 1, further comprising:
moving, by a sweep arm assembly coupled to the at least one polishing pad, the at least one polishing pad along a radial direction such that the at least one polishing pad overlies a conditioning ring; and
conditioning the at least one polishing pad with the conditioning ring.

9. The method of claim 8, wherein transferring the substrate off of the chuck is simultaneous to at least one of moving the at least one polishing pad along the radial direction and conditioning the at least one polishing pad with the conditioning ring.

10. The method of claim 9, wherein conditioning the at least one polishing pad comprises rotating a rotational motor coupled to a belt surrounding and in contact with the conditioner ring and rotational motor, such that rotation of the rotational motor causes rotation of the conditioner ring.

11. The method of claim 1, wherein polishing the substrate comprises controlling a pressure of the at least one polishing pad on the substrate by changing a pressure in a pressurizable membrane coupled to the at least one polishing pad and separated from the at least one polishing pad by a flexure.

12. The method of claim 11, further comprising replacing the polishing pad without removing the pressurizable membrane.

13. The method of claim 1, wherein transferring the substrate onto and off the chuck comprises raising and lowering lift pins embedded in the chuck to contact the substrate while a robotic arm moves along a horizontal direction above the chuck.

14. A chemical mechanical polishing system, comprising:
a chuck assembly comprising a chuck configured to hold a substrate during a polishing operation;
a motor to rotate the chuck about a first axis;
a pad carrier assembly that includes a support that is movably along a radial direction relative to the first axis, a lateral actuator coupled the support to cause the support to move along the radial direction, a pad carrier supported from the support and configured to receive and hold a polishing pad, and a pad carrier actuator to apply a downward pressure to the pad carrier; and
a conditioner ring positioned concentrically with the chuck, and wherein the support has a sweep range along the radial direction from a first position in which the polishing pad attached to the pad carrier is positioned over the chuck for polishing of the substrate and a second position in which the polishing pad is positioned over the conditioner ring for conditioning of the polishing pad.

15. The system of claim 14, comprising a controller configured to cause the lateral actuator to move the pad carrier and polishing pad from the first position to the second position after completion of polishing of the substrate.

16. The system of claim 14, comprising a vertical actuator to move the chuck vertically through an aperture in the conditioner ring between a raised position in which the substrate is positioned to contact the polishing pad and a lowered position in which the substrate is below the conditioner ring.

17. The system of claim 14, comprising a substrate robot transfer robot configured to load or unload the substrate from the chuck at the lower position.

18. A chemical mechanical polishing system, comprising:
a chuck assembly comprising a chuck configured to hold a substrate during a polishing operation;
a motor to rotate the chuck about a first axis;
a pad carrier assembly that includes a support that is movably along a radial direction relative to the first axis, a lateral actuator coupled the support to cause the support to move along the radial direction, a pad carrier supported from the support and configured to receive and hold a polishing pad, and a pad carrier actuator to apply a downward pressure to the pad carrier;
a substrate transfer robot to load and/or unload the substrate from the chuck; and
a vertical actuator to move the chuck vertically between a raised position in which the substrate is positioned to contact the polishing pad and a lowered position in which the substrate on the chuck is accessible to the substrate transfer robot.

19. The system of claim 18, comprising a horizontally extending support plate that supports the support of the pad carrier assembly, and wherein the lowered position is below the horizontally extending support plate.

20. The system of claim 18, wherein the substrate transfer robot has an end effector to hold the substrate, the end effector movable along a horizontal axis.

21. The system of claim 20, wherein the end effector is constrained to move along the horizontal axis.

22. The system of claim 18, comprising a conditioner ring positioned concentrically with the chuck, and wherein the support has a sweep range along the radial direction from a first position in which the polishing pad attached to the pad carrier is positioned over the chuck for polishing of the substrate and a second position in which the polishing pad is positioned over the conditioner ring for conditioning of the polishing pad, and wherein the vertical actuator moves the chuck vertically through an aperture in the conditioner ring.
